(19) United States
(12) Patent Application Publication
(10) Pub. No.: US 2009/0128242 A1
(43) Pub. Date: May 21, 2009

(54) FREQUENCY GENERATION IN A WIRELESS COMMUNICATION UNIT

(75) Inventor: Morgan Fitzgibbon, Carrigaline (IE)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 11/914,876

(22) PCT Filed: May 26, 2005
(86) PCT No.: PCT/EP05/52408

§ 371 Date: Nov. 19, 2007

(51) Int. Cl. H03L 7/00

(52) U.S. Cl. 331/17

(57) ABSTRACT

A wireless communication unit comprises a frequency generation circuit employing a fractional-based synthesiser, a voltage controlled oscillator circuit and a charge pump. A characterising function characterises a charge pump gain at a number of synthesized frequencies. A memory element is arranged to store characterised parameters. A scaling function is operably coupled to the memory element and the voltage controlled oscillator circuit and arranged to compensate for Kᵥ/N variation over a tuning line voltage applied to the voltage controlled oscillator circuit, at a synthesized frequency.

In this manner, the bandwidth (open loop gain) of a Phase Locked Loop remains relatively constant, to ensure the phase noise and lock time performance of the transmitter is better than 50 μsec and the Rx performance is better than 125 μs. Advantageously, only one loop filter is required to cover both Rx and Tx modes of operation.

### FIELD OF THE INVENTION

This invention relates to frequency generation circuits for wireless communication units. The invention is applicable to, but not limited to, a frequency generation circuit that uses fractional ‘N’ synthesiser technology.

### BACKGROUND OF THE INVENTION

Wireless communication units, for example those operating in a cellular telephone system such as the Global System for Mobile communications (GSM), use a broadcast reference frequency signal, for example a Frequency Correction Channel (FCCH), to calibrate their operating (transmit/receive) frequency. The broadcast signal is generally transmit from one or more base transceiver stations (BTSs). The wireless communication units use the frequency correction signal to synchronise their internal frequency generation circuits to a centralised timing system. The units synchronise their operating frequency to match the system frequency, prior to entering into a communication.

There are many known techniques for synthesizing modulated signals onto frequencies for transmission. A popular technique at present is one that uses a fractional division synthesizer, which enables a wide range of discrete frequencies to be tuned to by appropriate selection of ‘division’ parameters applied to a reference oscillator.

The 3^{rd} Generation Partnership Project 3GPP (previously standardised by European Telecommunication Standards Institute (ETSI)) has defined a frequency accuracy for digital cellular telecommunications, with one specification for the Global System for Mobile Communications (GSM) being defined in ‘Radio Transmission and Reception for Digital Cellular Telecommunication System in 3GPP TS 05.05’. This standard also specifies operating frequencies for ‘Quad-band’ enhanced general packet radio system (EGPRS) transceivers that cover low band GSM850, enhanced GSM (EGSM) and high band DCS1800 and PCS1900 frequencies. The accuracy of the synthesised VCO frequency has to be 0.1 ppm for current EGPRS based phones.

Such accurate frequencies can be generated in current wireless communication units, primarily by one of two methods:
(i) A voltage, temperature-controlled crystal oscillator (VTCXO). The accuracy of a VTCXO has a typical free running tolerance of the order of 2 ppm. Thus, these circuits need a digital-to-analogue converter (DAC) to ‘adjust’ the final frequency to improve the VTCXO's accuracy; and
(ii) Typical free-running crystal units have a frequency tolerance of the order of 30 ppm. This is three hundred times the tolerance required by the transmitter. The improvement in frequency accuracy, in order to meet the 3GPP standard's requirements, is typically achieved by adjusting a divider feedback ratio in a fractional-‘N’ phase locked loop (PLL). Unfortunately, this involves calculating a new synthesiser feedback ratio for every single PLL frequency.

A VTCXO implementation costs approximately three times that of a crystal (XTAL)-based implementation. Hence, with the manufacturing cost of wireless communication units being a key factor in achieving success in such a mass-market field, use of an XTAL-based solution is highly desirable.

With a free-running XTAL-based implementation, calculating a new feedback ratio for every frequency channel is needed. This requires a complex software algorithm. Automatic frequency control (AFC) circuitry is also needed, whereby an AFC value needs to be updated every time a new frequency is selected, or at least every time that a new AFC calculation is performed. In contrast, the VTCXO system only needs updating once a new frequency error is calculated.

A fractional ‘N’ based frequency generation approach is described in PCT Patent Application: WO97/28606 A1, by Motorola, Daniel et al., titled “Method and apparatus for controlling a fractional-n synthesiser in a time division multiple access system”.

A current trend in wireless radio frequency (RF) frequency generation is to use a frequency synthesizer, charge pump based fractional phase locked loop (PLL) that is a XTAL based implementation, as shown in FIG. 2. In this arrangement, the XTAL frequency is compared to a divided down to a Voltage Controlled Oscillator (VCO) frequency, and positive and negative frequency/phase errors are applied as either positive or negative going current pulses to a loop filter which are integrated to form a voltage. A tuning line voltage is applied to the VCO to synthesize an output frequency. When the divided down VCO frequency is comparable to the XTAL frequency, that is to say that from one reference cycle to the next the tuning line voltage remains the same, then the desired output VCO frequency has been achieved. This is known in the art as frequency synthesis by a phase locked approach. How well the system is locked depends upon the accuracy of the phase error, commonly referred to as ‘phase noise’.

The frequency accuracy as described before may be achieved by adding a digital automatic frequency correction (AFC) word to the divider values in order to achieve the sub 1 ppm VCO synthesized frequency.

A trend in wireless RF integrated circuit (IC) design is towards digital CMOS processes. The trend of implementing CMOS VCOs in these processes is to use a digital coarse tuned bank of varactors, manufactured on CMOS technology. For a relatively fixed tuning line (say, 1.35V+/−400 mV) a bank of (say, ‘32’) binary weighted varactors is used to implement the required tuning range for GSM ‘Quad-band’ applications. Over this tuning range the capacitance varies the frequency. Hence, the small signal gain of the VCO, Kᵥ, varies. Kᵥ is measured in MHz/V from 60 MHz/V for a N=124 (low end of GSM850 Band) to a Kᵥ=124 MHz/V for a N=147 (high end of the PCS Band).

The loop gain determines the bandwidth (BW) of the PLL and hence the lock time and the phase noise performance of the PLL. The loop gain product of the phase locked loop (PLL) is known to be:

Kₚₕᵢ*Kᵥ*H(s)/N [1]

### Where:

‘Kphi’ is the Charge Pump Gain;
‘Kv’ is the VCO Gain;
‘H(s)’ is the transfer function (gain and phase) of the loop filter, as described by Laplace notation; and
‘N’ is the fractional divider value.

However, it is known that it is difficult to achieve the GSM quad-band phase locked loop (PLL) lock times for receive (Rx) and transmit (Tx) modes.

It is also known to be difficult to achieve the phase noise requirements for both Rx and Tx modes over power, voltage and temperature (PVT) variations. Hence, two loop filters are used—one for Rx mode and one for Tx mode.

The most difficult specification to meet is the VCO 20 MHz offset noise spec. (of −164.7 dBc/Hz). A further trend in cost-driven GSM phones is to eliminate the bulky transmit surface acoustic wave (SAW) filters.

With the aforementioned variation of the VCO's small signal gain, a closed loop bandwidth variation of approximately 70 kHz results when implemented using one loop filter.

U.S. Pat. No. 5,144,264 describes a method for compensating the variation of the open loop gain over frequency within a Colpitts VCO. In particular, the authors describe compensating the open loop gain variation by changing the well known Colpitts feedback topology by adding another inductor in series with C1, in order to boost the open loop gain at lower frequencies, which tends to increase the capacitance. If this method is used the inductor component takes up a relatively large IC area on the chip. Also this inductor would require tuning, i.e. the inductor would require to be broken up into segments to achieve more accurate tuning over the desired frequency bands.

Single-ended Colpitts oscillators are rarely, if ever, utilised in current GSM transceiver VCOs. It is well known that cross-coupled differential NMOS, PMOS or CMOS resonant circuits, placed across the ‘tank circuit’, are often utilised to achieve the required phase noise and frequency response. Differential circuits are preferable over single ended ones because of the ‘2×’ signal swing achieved as well as the common mode rejection properties inherent with differential circuits.

However, it is also known that it is problematic to achieve adequate linearity of open loop gain compensation over frequency when using such techniques.

U.S. Pat. No. 6,693,496 proposes scaling the charge-pump current in proportion to the VCO current and inversely proportional to the frequency range associated with the divider number, N. Furthermore, the loop filter resistor is made inversely proportional to the square root of the VCO current and proportional to N.

However, such a proposal suffers from having to scale:
(i) Charge Pump Current in proportion to two parameters—VCO current and inversely to frequency; and
(ii) The Loop Filter resistor in proportion to N and the square root of VCO current.

Thus, a need has arisen to provide a wireless communication unit, an application specific integrated circuit and a method of generating a radio frequency signal, wherein the aforementioned disadvantages may at least be alleviated.

### STATEMENT OF INVENTION

In accordance with preferred embodiments of the present invention, there is provided a wireless communication unit, an integrated circuit and a method of generating a radio frequency signal, as defined in the appended Claims.

### BRIEF DESCRIPTION OF THE DRAWINGS

Exemplary embodiments of the present invention will now be described, with reference to the accompanying drawings, in which:

FIG. 1 illustrates a block diagram of a wireless communication unit, adapted to support the various inventive concepts of the present invention;

FIG. 2 illustrates a block diagram of a frequency generation circuit of a wireless communication unit, adapted to support the various inventive concepts of the present invention;

FIG. 3 illustrates a graph of frequency response of a VCO coarse tuning operation according to a preferred embodiment;

FIG. 4 illustrates a graph of VCO Kᵥ according to a preferred embodiment of the present invention;

FIG. 5 illustrates, in tabular form, how the charge pump gain may be scaled with respect to the data taken from the circuit of FIG. 3, according to a preferred embodiment;

FIG. 6 illustrates, in tabular form, how the threshold may be selected using the inventive concept of the present invention; and

FIG. 7 shows a flowchart of a frequency generation mechanism according to the preferred embodiment of the present invention.

### DESCRIPTION OF PREFERRED EMBODIMENTS

In summary, the preferred embodiment of the present invention proposes to solve the aforementioned problems by using a characterisation of the charge pump gain, Kₚₕᵢ and in particular tuning to compensate Kᵥ/N variation over the tuning line voltage.

As explained previously the closed loop gain is dependent on equation [1]. Hence, if the charge pump gain is scaled in proportion to Kᵥ/N then the closed loop gain remains effectively constant, as does the bandwidth (BW).

One factor in the scaling of Kₚₕᵢ in proportion to Kᵥ/N variation is an understanding of how Kᵥ/N varies, for example it is important to ascertain how Kᵥ/N varies, say in a substantially linear or 1^{st} order or 2^{nd} order, etc. response. In accordance with the preferred embodiment of the present invention, it is assumed that Kᵥ/N varies in a substantially linear or 1^{st} order manner, based on the particular VCO topology described.

However, it is within the contemplation of the present invention that if the Kᵥ/N variation was a more complex response, a system could be designed by a skilled artisan that could readily utilise the inventive concept herein after described.

Advantageously, the inventive concept provides a relatively constant BW over the Tx tuning range. Consequently, an enhanced feature of the present invention is that the Rx tuning range can be incorporated with the same loop filter. This enhanced feature can be implemented by using a different charge pump gain setting to set the BW of the filter and keep that BW relatively constant too. The use of a single loop filter, in contrast to the standard use of two distinct loop filters, facilitates a reduction in component count (as at least five surface mount components can be removed) as well as the circuit board area required to implement a frequency generation circuit.

Furthermore, a skilled artisan will appreciate that the use of a single loop filter facilitates integration of the filter on a chip.

The preferred embodiment of the present invention uses one parameter, namely the charge pump current to achieve the aforementioned advantages. Consequently, the preferred embodiment provides an arrangement that is more robust over process (using currents), voltage (current independent) and temperature (through temperature compensation). This is achieved by using an external 1% resistor 232 to set the charge pump current reference current.

The charge pump gain tracking preferably provides ‘16’ levels of tracking for Rx and Tx modes. Additionally, the charge pump gain tracking is implemented utilising a minimal amount of silicon area, due to the monotonic nature of the voltage controlled oscillator (VCO) variation. In the context of the present invention the term ‘monotonic’ describes the relationship that as N increases positively (i.e. the frequency increases) then the Kv also increases positively. Effectively, this happens between a minimum value of Kv/N and the maximum value of Kv/N, where a line can be drawn between these two points to approximate all the values of Kv/N in between.

Also, the consequent increase in silicon area of the charge pump, due to the extra current source elements required for Kphi tuning, does not have a comparable effect on charge pump phase noise performance.

Advantageously, this charge pump gain tracking implementation does not require factory phasing and is transparent to the user. The reason that factory phasing is no longer required is that when the user selects a certain channel or divider setting, then this channel or setting corresponds to a Kₚₕᵢ tuning word compensating for a corresponding Kᵥ/N. Kᵥ/N is characterised by process models over PVT. Through experimentation, the ‘16’ steps of Kₚₕᵢ tuning resolution was found to provide acceptable robustness of Kᵥ/N variation over PVT. Hence, closed loop gain for both Tx and Rx modes of operation meet the desired performance levels. The charge pump circuit itself is also robust to PVT variations as stated above.

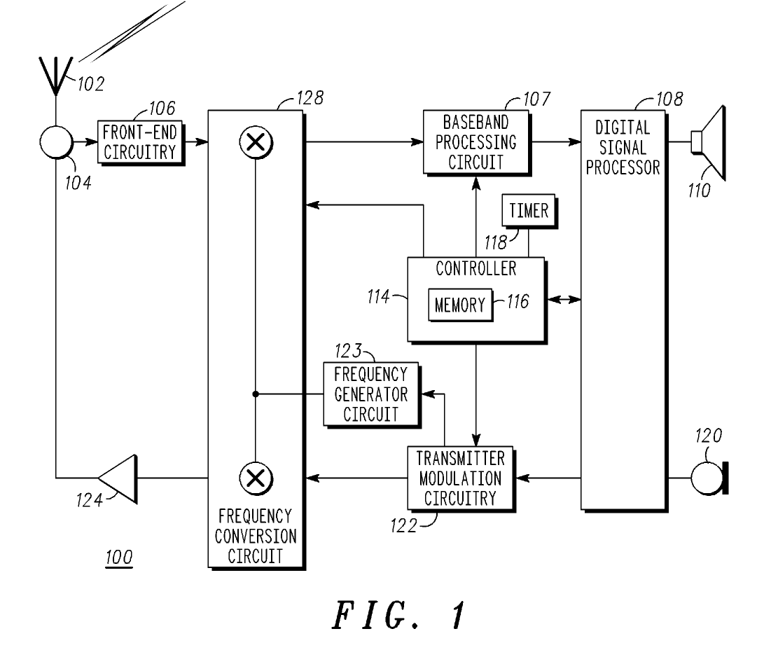

A block diagram of a wireless subscriber communication unit (often termed mobile station (MS)) 100 is shown in FIG. 1. The MS 100 is adapted to support the inventive concept of the preferred embodiment of the present invention. The MS 100 contains an antenna 102 preferably coupled to a duplex filter or antenna switch 104 that provides isolation between receive and transmit chains within the MS 100.

The receiver chain includes receiver front-end circuitry 106 (effectively providing reception, amplification and filtering of a received signal). The received signal is input to a frequency conversion circuit 128 that receives a reference oscillator signal from the frequency generation circuit 123. The frequency conversion circuit 128 preferably comprises mixing and amplifier elements (not shown), as known in the art. The frequency conversion circuit 128 is serially coupled to a signal processing function (generally realised by a digital signal processor (DSP)) 108 via a baseband (back-end) processing circuit 107.

A controller 114 is operably coupled to the frequency generation circuit 123 and/or frequency conversion circuit 128. A memory device 116 stores a wide array of MS-specific data, for example decoding/encoding functions, frequency and timing information for the communication unit, etc. A timer 118 is operably coupled to the controller 114 to control the timing of operations, namely the transmission or reception of time-dependent signals, within the MS 100. As known in the art, received signals that are processed by the signal processing function are typically input to an output device 110, such as a speaker or liquid crystal display (LCD).

The transmit chain essentially includes an input device 120, such as a microphone, coupled in series through a processor 108, transmitter/modulation circuitry 122, frequency generation/conversion circuit 128 and a power amplifier 124. The processor 108, transmitter/modulation circuitry 122 and the power amplifier 124 are operationally responsive to the controller. An output from the power amplifier is coupled to the duplex filter or antenna switch 104, as known in the art.

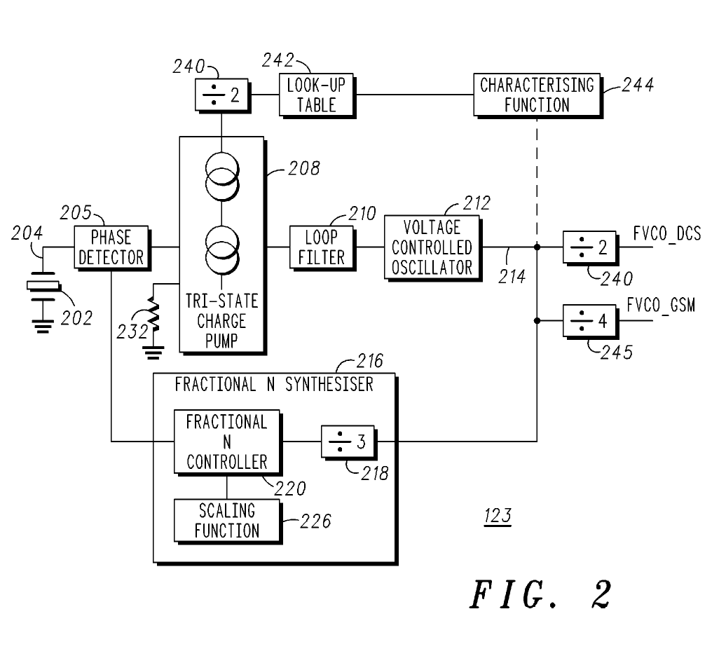

In accordance with a preferred embodiment of the present invention, the radio frequency generation circuit 123 incorporates a fractional ‘N’ frequency synthesizer with a phase locked loop (PLL) and arranged to have constant open loop gain. The constant open loop gain is achieved by compensating the gain variation of the VCO with the gain of the charge pump, as described in greater detail with respect to FIG. 2.

Kv/N is characterised by process models over Process, Voltage (including tuning line voltage) and bias voltage of the VCO, over Temperature (PVT). Through experimentation, it was determined that ‘16’ steps of Kphi Tuning resolution was sufficient to provide acceptable robustness of Kv/N variation over PVT in the circuit of the preferred embodiment. Hence, this facilitates a closed loop gain performance for both a Tx mode of operation (using ‘8’ steps) and a Rx modes of operation (using ‘8’ steps). The ‘8’ steps for Tx operation are preferably spread evenly over the four frequency Bands, two steps for each frequency band based on the divider setting N. The divider setting then selects a Kphi tuning word to compensate a corresponding Kv/N value.

Of course, the various components within the wireless communication unit 100 may be realised in discrete or integrated component form. Furthermore, it is within the contemplation of the invention that the wireless communication unit 100 may be any wireless communication unit, such as a portable phone, a portable or mobile radio, a personal digital assistant, a wireless laptop computer, etc.

More generally, any re-programming or adaptation of one or more software algorithms, or data banks associated with the frequency generation circuit 123, may be implemented in any suitable manner. For example, a new signal processor function or memory device may be added to a conventional wireless communication unit 100. Alternatively, existing parts of a conventional wireless communication unit may be adapted, for example by reprogramming one or more processors therein. As such, the required adaptation may be implemented in the form of processor-implementable instructions stored on a storage medium, such as a floppy disk, hard disk, programmable read-only memory (PROM), random access memory (RAM), or any combination of these or other storage media.

The preferred embodiment of the present invention is described with reference to a fractional ‘N’ synthesiser design in a MS 100. However, it is envisaged that the inventive concepts herein described are equally applicable to any synthesiser design.

Referring now to FIG. 2, the frequency generation circuit 123 of the preferred embodiment of the present invention is illustrated in greater detail. The preferred embodiment of the present invention is targeted towards frequency synthesis generation for an enhanced general packet radio system (EGPRS). In this regard, the frequency synthesis generation circuit is capable of 2.75G EDGE/GSM/GPRS applications, and/or indeed a number of other wireless protocols.

The frequency generation circuit 123 comprises a PLL including a free-running crystal oscillator arrangement 202, 204 providing an oscillator signal (say, a reference signal of 26 MHz) to a phase detector 205 of a phase locked loop (PLL) circuit. The phase detector 205 detects the phase difference between the divided VCO output signal 214 and the free-running crystal oscillator reference signal 204. The phase detector 205 outputs a signal to a tri-state charge pump 208, having an intentional leakage current to guarantee phase lock. The charge pump 208 introduces current into, or out of, a classic lead-lag loop filter 210, in proportion to the detected phase difference, as known in the art.

The output from the charge pump 208 is filtered by loop filter 210 and input to a coarse-tuned voltage-controlled oscillator (VCO) 212 having 5-bit binary weighted varactors, i.e. ‘32’ tuning curves to cover the required frequency range (Tx GSM 850, Tx EGSM900, Tx DCS and Tx PCS bands, together with comparable Rx bands) over the tuning line voltage range of 1.3V+/−400 mV.

In a GSM unit, the VCO output (for quadrature purposes) is typically arranged to be a frequency in the GHz range. The loop filter 210 is used to set the main loop dynamics, as well as filtering spurs and noise. In a GSM unit, this is often configured to have a 3 dB cut-off frequency of 150 KHz in order to achieve the necessary lock time.

The VCO output signal 214 is fed to the Tx and/or Rx local oscillator (LO) circuits or Rx Quad generator of the wireless communication unit. For example, the VCO output signal 214 is fed into a divide-by-two divider 240 to produce a direct communication system (DCS) and/or a personal communication system (PCS) cellular frequency signals. The VCO output signal 214 is also fed into a divide-by-four divider 245 to produce a GSM 850 MHz and EGSM900 (in Europe) frequency band signal.

The phase locked loop arrangement further comprises a fractional ‘N’ synthesiser design 216 operably coupling the VCO output signal to the phase detector 205, to maintain accurate phase control of the oscillator signal. In the feedback path, the fractional ‘N’ synthesiser 216 comprises a divider, say a divide-by-three function 218, operably coupled to a quantisation noise-shaping fractional N controller 220. The fractional N divider is preferably modulated by GMSK and EDGE waveform generators. In the preferred embodiment of the present invention, this PLL forms part of a direct launch modulator for GMSK and EDGE (Polar) applications.

This quantisation noise-shaping fractional N controller function 220 typically comprises multiple accumulators in a sigma-delta ‘mash’ construct, as shown in the art. The accumulators are typically clocked off the feedback frequency of the PLL. The fractional-N controller function 220 receives a scaling function 226 to scale the accumulator value, and outputs to the phase detector 205. The noise shaping is performed due to the mash construct in which these accumulators are coupled. In this regard, the noise shaping shapes the quantisation noise for the system.

In accordance with the preferred embodiment of the present invention, the dynamic operation of the PLL is dominated by the open loop gain of the system. Thus, first the VCO performance is characterised over a range of operating conditions (voltage, temperature, etc.) over a number of synthesised frequencies. The characterising function 244 is preferably a frequency analyser, which may be a stand-alone test equipment item or a signal processor operably coupled to the frequency generation circuit 123. However, it is envisaged that the characterising function 244 may encompass any signal processing function that is able to measure a VCO's performance across a frequency range. The characterised parameters are stored in a look-up table 242, or other suitable memory element, operably coupled to the characterising function 244, for later use.

In particular, knowledge of the gain of the VCO (Kᵥ) is obtained by the characterising function 244. Thereafter, knowledge of how Kᵥ varies over frequency (N) is stored in the look-up table 242 and used by a scaling function 240 (such as a signal processor) to weight (scale) the Charge Pump Gain (Kₚₕᵢ) in order to keep the open-loop gain constant.

An external accurate resistor, say a 1% resistor, 232 is used to set the charge pump current reference current, thereby providing more robustness of the design over PVT.

Advantageously, the tracking is kept simple in that the system takes advantage of the fact that the Kᵥ/N variation is monotonic with increasing frequency. As the gain of the VCO, Kᵥ, varies in frequency, then the open loop gain of the system varies, as determined by the characterising function 244. Hence, the closed loop gain (G_{cl}) also varies. Furthermore, the bandwidth (BW) varies. However, as known in the art of wireless cellular communication, stringent noise requirements are to be achieved at various offsets from the synthesised carrier, such as the 400 kHz offset (−125 dBc/Hz) and 20 MHz offset (−165 dBc/Hz) and these cannot achieved if the bandwidth varies.

Consequently, the inventor of the present invention has recognised and appreciated that if the bandwidth of the PLL is made narrower to meet the phase noise offsets, then the bandwidth (BW) would be too narrow. Hence, the lock time of the PLL is affected.

Therefore, the present invention proposes a mechanism to keep the BW of the PLL relatively constant, thereby meeting the phase noise and lock time requirements of the PLL. The present invention proposes to use a single loop filter for both Rx and Tx Modes of operation, in contrast to prior art mechanisms where traditionally two separate loop filters are used.

A substantially linear or 1^{st} order variation of Kᵥ versus frequency ‘N’ from 60 MHz/V, with N=124 to Kv=124 MHz/V, with N=147 is assumed, which is more than adequate to accommodate variations in process, voltage and temperature of the system. However, it is within the contemplation of the present invention that similar Kᵥ's and N's can be used in other applications to provide similar advantages. The delta in BW variation is 70 kHz, before Kₚₕᵢ compensation/tuning. Advantageously, using the inventive concept described herein, the BW is better than 10 kHz over Process, Voltage and Temperature variations.

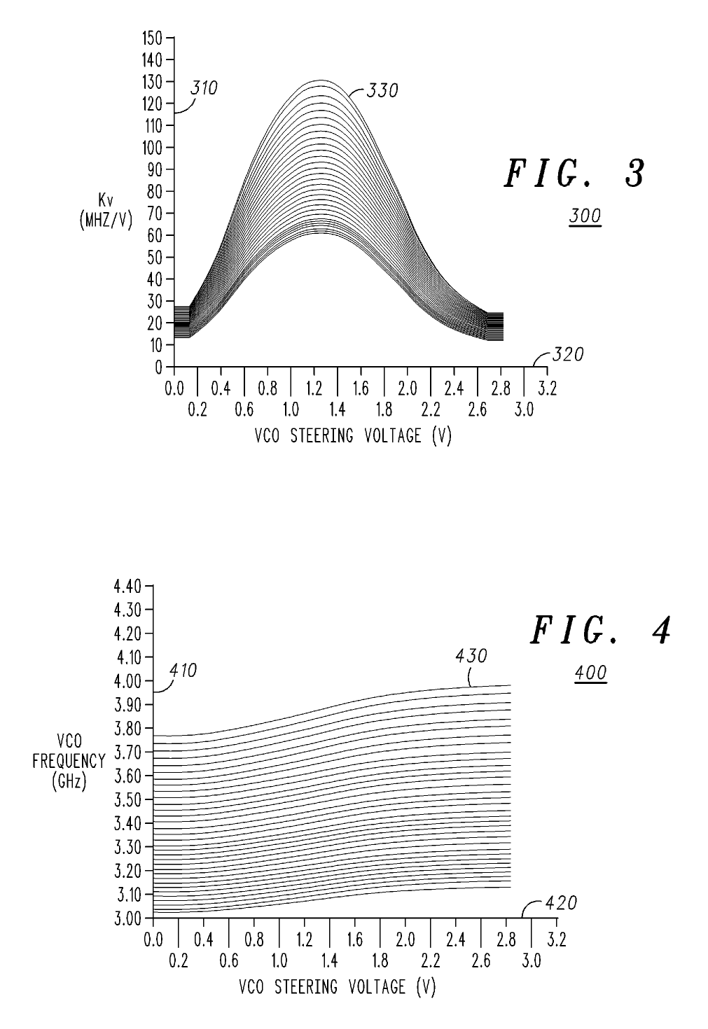

FIG. 3 and FIG. 4 illustrate how the Kᵥ/N variation is monotonic with increasing frequency and how the Gain varies over the frequency range, i.e. the complete Tx frequency range of the GHz VCO (that is 2× the DCS and PCS Bands, 4× the GSM900 and EGSM850 bands).

In particular, FIG. 3 illustrates a graph 300 of frequency response of the VCO course tuning operation 330, with the VCO frequency 310 plotted against the VCO steering voltage 320. FIG. 3 illustrates how the Gain (Kv) varies over this tuning range (i.e. the VCO steering voltage) highlighting that the gain variation is monotonic (if, for example, a straight line is drawn for a steering line voltage of 1.35V).

FIG. 4 illustrates a graph 400 of VCO Kᵥ 430, with the Kᵥ 410 plotted against the VCO steering voltage 420. For a nominal voltage of 1.3V+/−400 mV, the complete tuning Tx range is achieved.

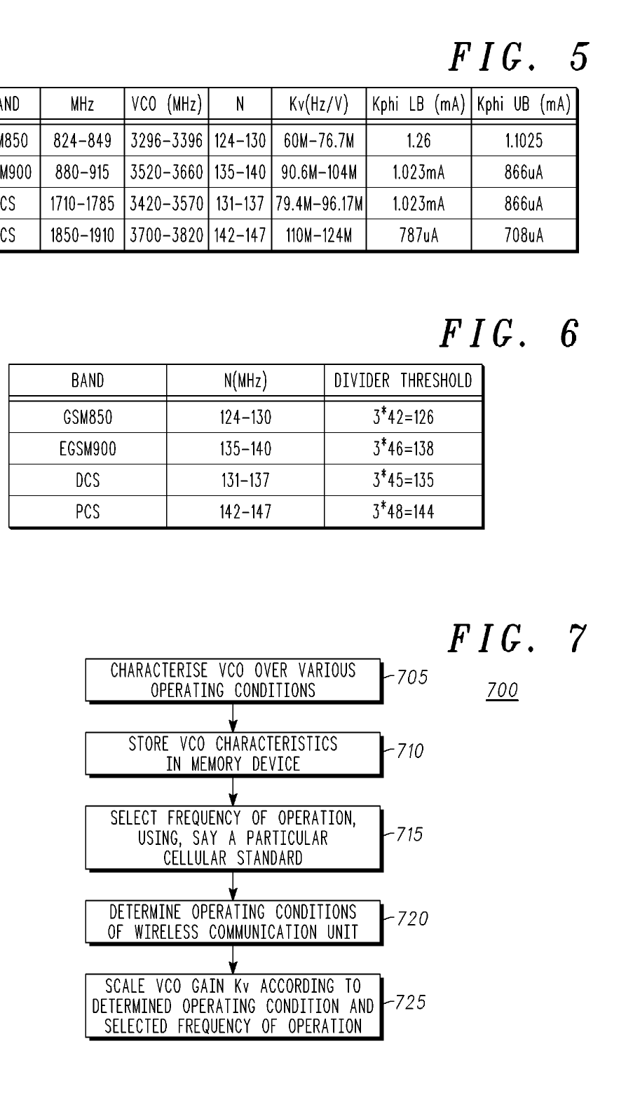

FIG. 5 illustrates a table of how, for example, the charge pump gain may be scaled with respect to the data taken from FIG. 3. Note in table 5 that there are effectively eight steps, two steps per band, upper and lower part of the band, with a similar arrangement for Rx.

The divide-by-3 function, for example the function 218 as illustrated in FIG. 2, is used as a threshold to select between the upper part and the lower part of the band.

FIG. 6 illustrates an example table of how the threshold may be selected using the inventive concept of the present invention to select between the upper and lower part of the frequency band.

The inventive concept of the present invention finds particular use in radio frequency (RF) PLLs/synthesisers for wireless applications, such as GSM, GPRS, EDGE, CDMA etc. An attractive feature of the proposed embodiment is that it can be applied to any type of Charge Pump PLL (or other active component as part of the phase detecting process), for example operating according to the following set of equations:

F_{VCO}=N×F_{Ref}×G_{CL} [2]

Where:

G_{CL}=G_{OL}/1+G_{OL} [3]

which sets the bandwidth.

F_{VCO}(DCS)=F_{VCO}/2= [4]

1/(1+(G_{OL}))−1 [5]

F_{VCO}(GSM)=F_{VCO}/4 [6]

When G_{OL} is constant, then the bandwidth remains relatively constant.

In summary, the preferred embodiment of the present invention proposes the following process, as illustrated in the flowchart 700 of FIG. 7. First, the VCO of the communication unit is characterised using a coarse-tuned binary weighted varactor. This characterization process is performed over frequency for all operating conditions, such as voltage conditions (tuning line and power supply), temperature, etc. as shown in step 705. The communication unit then stores these VCO characteristics in a memory device, such as look up table 242 in FIG. 2, as shown in step 710. When the wireless communication unit is required to communicate, i.e. transmit or receive information, a frequency of operation is selected in step 715.

The wireless communication unit, for example with a signal processor located therein, determines operating conditions that are prevalent within the wireless communication unit, such as operating temperature, supply voltage, etc., as shown in step 720. Thereafter, a scaling function, such as the signal processor 240 operably coupled to the charge pump circuit of FIG. 2, automatically scales the VCO's gain, based on the synthesized frequency selected at these characterised operating conditions of the VCO, as shown in step 725.

The steps 715, 720 and 725 are then repeated upon each change in operating frequency, or when one or more of the operating conditions vary sufficient to exceed a particular threshold. The threshold, in this context, indicates that a new VCO gain needs to be selected, due to significant variation in the operation of the wireless communication unit.

In this manner, the bandwidth (open loop gain) of the PLL remains relatively constant, to ensure the phase noise performance has better than a 10 dB phase margin and lock time performance is acceptable (e.g. Tx performance is better than 50 μsec, Rx performance is better than 125 μs). Advantageously, only one loop filter is required for both Rx and Tx Modes of operation, thereby saving component count, die area and circuit complexity.

Advantageously, this process facilitates a reduction in die area as well as reducing cost for the customer in terms of factoring phasing and component count.

According to the preferred embodiment of the present invention, the implementation of using the aforementioned charge pump gain technique is advantageously well within 1% of variation of tuning line range, i.e. the tuning frequency per tuning curve.

Although the present invention has been described with reference to fractional ‘N’ synthesiser designs, it is envisaged that the inventive concept described is equally applicable to any transceiver where an accurate free running crystal oscillator is used. In particular it is envisaged that the inventive concept is most applicable, at the present time, to transceivers used with an enhanced general packet radio system (EGPRS), a digital video broadcast (DVB) system, a wireless local area network (WLAN), a wireless private access network (WPAN) etc., where frequency synthesizers are typically implemented based on charge pump PLLs.

It is also within the contemplation of the present invention that the inventive concept can be used in any charge pump circuit. Furthermore, it is within the contemplation of the present invention that the inventive concept can be applied equally to alternative active elements to charge pumps in order to compensate for VCO variations, for example in an exclusive ‘OR’ phase detector arrangement the power supply of the XOR phase detector could be varied to achieve a similar response.

It is envisaged that integrated circuit manufacturers are able to manufacture integrated circuits comprising the aforementioned fractional ‘N’ synthesiser elements/components and arranged to perform voltage controlled oscillator functions based on the new configuration, as hereinbefore described. It is also envisaged that the aforementioned inventive concept can be applied to most transceiver architectures and platform solutions, i.e. a semiconductor manufacturer may employ the inventive concepts in a design of a stand-alone RFIC, an application-specific integrated circuit (ASIC) and/or any other frequency generation sub-system element.

Whilst specific, and preferred, implementations of the present invention are described above, it is clear that one skilled in the art could readily apply variations and modifications of such an inventive concept.

Thus, a wireless communication unit, an integrated circuit and a method for generating a radio frequency signal in a wireless communication unit have been provided where the disadvantages described with reference to prior art arrangements have been substantially alleviated.

1. A wireless communication unit comprises:
a frequency generation circuit employing a fractional-based synthesiser operably coupled to a voltage controlled oscillator circuit and a charge pump, wherein the wireless communication unit includes a characterising function that characterises a charge pump gain at a number of synthesized frequencies;
a memory element operably coupled to the characterising function is arranged to store characterised parameters and a scaling function operably coupled to the memory element; and
the charge pump is arranged to compensate for open-loop Kᵥ/N variation over a tuning line voltage applied to the voltage controlled oscillator circuit at a synthesized frequency.

2. The wireless communication unit according to claim 1 wherein the scaling function scales a charge pump phase locked loop (PLL) current to automatically scale the open-loop voltage controlled oscillator's gain.

3. The wireless communication unit according to claim 1 wherein the characterising function of the voltage controlled oscillator is a coarse-tuned binary weighted varactor.

4. The wireless communication unit according to claim 1, wherein the characterising function determines how open-loop Kᵥ/N varies, for example as a linear or 1^{st} order or 2^{nd} order gain versus frequency response.

5. The wireless communication unit according to claim 1, wherein the wireless communication unit comprises a receive chain and a transmit chain where the frequency generation circuit comprises a single loop filter used to generate both transmit and receive frequencies.

6. The wireless communication unit according to claim 5 wherein a first charge pump gain setting is used to set a first closed loop bandwidth of the PLL for a transmit mode of operation and set a second closed loop bandwidth of the PLL for a receive mode of operation.

7. The wireless communication unit according to claim 1, wherein the wireless communication unit is a mobile phone arranged to support one or more cellular communication standards such as GSM, 3GPP, GPRS, EGPRS, EGSM.

8. An integrated circuit comprising:
a frequency generation circuit and a fractional-N based synthesiser for operably coupling to a voltage controlled oscillator and a charge pump, wherein the integrated circuit is arranged to be coupled to a characterising function to characterise a charge pump gain at a number of synthesized frequencies and store the characteristics in a memory element wherein the integrated circuit comprises, or is operably coupled to, a scaling function operably coupled to the memory element and the charge pump is arranged to compensate for open-loop Kᵥ/N variation over a tuning line voltage applied to the voltage controlled oscillator circuit, at a synthesized frequency.

9. The integrated circuit according to claim 8 wherein the scaling function scales a charge pump phase locked loop current to automatically scale the open-loop voltage controlled oscillator's gain.

10. The integrated circuit according to claim 8 wherein the characterising function of the voltage controlled oscillator is a coarse-tuned binary weighted varactor.

11. The integrated circuit according to claim 8, wherein the characterising function determines how open-loop Kᵥ/N varies, for example as a linear or 1^{st} order or 2^{nd} order gain versus frequency response.

12. The integrated circuit according to claim 8, further comprising a single loop filter used to generate both a transmit and a receive frequency.

13. The integrated circuit according to claim 12 wherein a first charge pump gain setting is used to set a first closed loop bandwidth of the PLL for a transmit mode of operation and set a second closed loop bandwidth of the PLL for a receive mode of operation.

14. A method of generating a radio frequency signal in a wireless communication unit comprising a frequency generation circuit employing a fractional-N based synthesiser and a voltage controlled oscillator and a charge pump, the method comprising the steps of:
characterising a charge pump gain of the voltage controlled oscillator circuit at a number of synthesized frequencies; and
scaling a tuning line voltage applied to the voltage controlled oscillator to compensate for open-loop Kᵥ/N variation, at a synthesized frequency over the range of operating conditions.

15. A method of generating a radio frequency signal according to claim 14, further comprising the steps of:
determining one or more operating condition(s) of the wireless communication unit; and
selecting a scaling value, in response to the step of determining, and using this scaling value in a step of setting the tuning line voltage.

16. A method of generating a radio frequency signal according to claim 14, further comprising the steps of:
determining how open-loop Kᵥ/N varies, for example as a linear or 1^{st} order or 2^{nd} order gain versus frequency response.

17. The method of generating a radio frequency signal according to claim 14, wherein the step of selecting a scaling value comprises selecting a scaling value to compensate for Kᵥ/N variation over the tuning line voltage.

18. The method of generating a radio frequency signal according to claim 14, wherein the step of selecting comprises selecting a charge pump phase locked loop current to automatically scale a voltage controlled oscillator's gain.

19. The method of generating a radio frequency signal according to claim 14, by further comprising the steps of setting a first charge pump gain to set a first closed loop bandwidth of a PLL for a transmit mode of operation and setting a second closed loop bandwidth of the same PLL for a receive mode of operation.

20-21. (canceled)
